(19) United States
(12) Patent Application Publication
(10) Pub. No.: US 2025/0175134 A1
(43) Pub. Date: May 29, 2025

(54) CIRCUIT SYSTEM CAPABLE OF REDUCING LAYOUT AREA AND OPERATING METHOD

(71) Applicant: Realtek Semiconductor Corporation, Hsinchu (TW)

(72) Inventors: Zhen Cheng ZHANG, Hsinchu (TW); Chih-Lung CHEN, Hsinchu (TW)

(21) Appl. No.: 18/954,507

(22) Filed: Nov. 20, 2024

(30) Foreign Application Priority Data
Nov. 23, 2023 (TW) 112145379

(51) Int. Cl. H03F 3/45

(52) U.S. Cl. CPC H03F 3/45475; H03F 2200/129

(57) ABSTRACT

A circuit system includes an amplifier, a variable capacitor and a switching circuit. The amplifier includes a first input terminal, a second input terminal and an output terminal. The output terminal is configured to generate an output voltage. The variable capacitor is coupled with the first input terminal. The switching circuit is coupled with the amplifier and the variable capacitor. In a calibration phase, the switching circuit is configured to disconnect the second input terminal and the output terminal, so that the amplifier is operated as a comparator. In the calibration phase, a capacitance value of the variable capacitor is calibrated according to the output voltage. In a power supplying phase, the switching circuit is configured to electrically connect the second input terminal and the output terminal to form a negative-feedback loop of the amplifier.

### RELATED APPLICATIONS

This application claims priority to Taiwan Application Serial Number 112145379, filed Nov. 23, 2023, which is herein incorporated by reference.

### BACKGROUND

### Technical field

The present disclosure relates to the integrated circuit technology, and in particular, to a circuit system saving a layout area and an operating method thereof.

### Description of Related Art

Current chips are equipped with capacitive elements for various purposes. Affected by process variation, capacitance values of these capacitive elements may vary in a considerable range. In addition, resistance values of resistive elements in the chip may also change with the operating temperature. Therefore, the common practice in the industry is to add an automatic capacitance calibration mechanism to the chip to achieve accurate control of a ratio of the capacitance to the resistance. A calibration circuit usually takes up a considerable amount of space. However, the calibration circuit is usually not used in most of the operating time of the chip, which considerably reduces the space utilization efficiency of the chip.

### SUMMARY

The present disclosure provides a circuit system, including an amplifier, a variable capacitor and a switching circuit. The amplifier includes a first input terminal, a second input terminal and an output terminal. The output terminal is configured to generate an output voltage. The variable capacitor is coupled with the first input terminal. The switching circuit is coupled with the amplifier and the variable capacitor. In a calibration phase, the switching circuit is configured to disconnect the second input terminal and the output terminal, so that the amplifier is operated as a comparator. In the calibration phase, a capacitance value of the variable capacitor is calibrated according to the output voltage, so that a voltage of the first input terminal approximates to a voltage of the second input terminal. In a power supplying phase, the switching circuit is configured to electrically connect the second input terminal and the output terminal to form a negative-feedback loop of the amplifier, in order to utilize the negative-feedback loop of the amplifier to stabilize the output voltage.

The present disclosure provides an operating method applicable to a circuit system. The circuit system includes an amplifier, a variable capacitor and a switching circuit. The switching circuit is coupled with the amplifier and the variable capacitor. The amplifier includes a first input terminal, a second input terminal and an output terminal, and the output terminal is configured to generate an output voltage. The operating method includes the following steps: in a calibration phase, utilizing a switching circuit to disconnect the second input terminal and the output terminal, so that the amplifier is operated as a comparator; in the calibration phase, calibrating a capacitance value of the variable capacitor according to the output voltage, so that a voltage of the first input terminal approximates to a voltage of the second input terminal; in a power supplying phase, utilizing the switching circuit to electrically connect the second input terminal and the output terminal to form a negative-feedback loop of the amplifier; and in the power supplying phase, utilizing the negative-feedback loop of the amplifier to stabilize the output voltage.

One of the advantages of the circuit system and the operating method is to improve the space utilization efficiency of the chip.

### BRIEF DESCRIPTION OF THE DRAWINGS

FIG. 1 is a simplified function block diagram of a circuit system according to an embodiment of the present disclosure;

FIG. 2 is a flowchart of an operating method according to an embodiment of the present disclosure;

FIG. 3 is a detailed flowchart of steps of an operating method according to an embodiment of the present disclosure;

FIG. 4 is a detailed flowchart of steps of an operating method according to an embodiment of the present disclosure;

FIG. 5 is a simplified function block diagram of a noise suppression circuit according to an embodiment of the present disclosure;

FIG. 6 is a detailed flowchart of steps of an operating method according to an embodiment of the present disclosure; and

FIG. 7 is a simplified function block diagram of a noise suppression circuit according to an embodiment of the present disclosure.

### DETAILED DESCRIPTION

Embodiments of the present disclosure are illustrated below in combination with related figures. In the figures, the same reference numerals represent the same or similar elements or method flows.

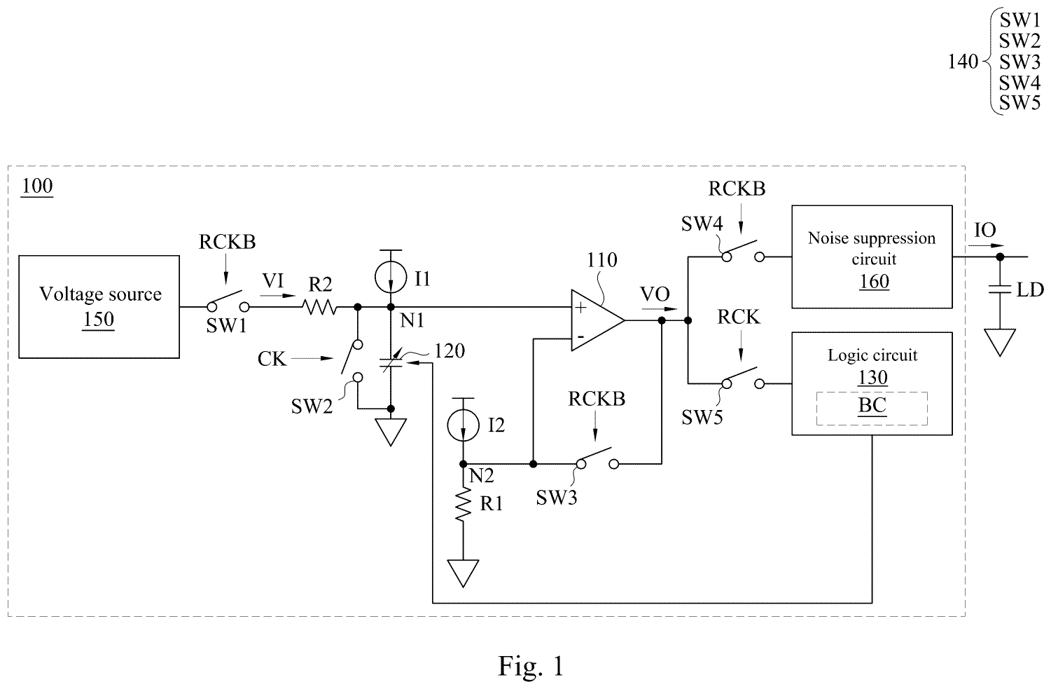

FIG. 1 is a simplified function block diagram of a circuit system 100 according to an embodiment of the present disclosure. The circuit system 100 includes an amplifier 110, a variable capacitor 120, a logic circuit 130, a switching circuit 140, a voltage source 150, a noise suppression circuit 160, current sources I1-I2, and resistors R1-R2. The circuit system 100 can be provided inside a chip. The circuit system 100 is configured to generate an output current IO that is not sensitive to temperature changes according to an input voltage VI to drive a load LD in the chip. In some embodiments, the circuit system 100 is configured to calibrate the variable capacitor 120, and configured to further calibrate other capacitive elements (not shown) in the chip according to a calibration result of the variable capacitor 120.

The amplifier 110 includes a first input terminal (for example, a non-inverting input terminal), a second input terminal (for example, an inverting input terminal) and an output terminal, where the output terminal is configured to generate an output voltage VO. The variable capacitor 120 is coupled with a first input terminal of the amplifier 110. Specifically, the first input terminal is coupled between a first terminal of the variable capacitor 120 and the current source I1 through a node N1, where a second terminal of the variable capacitor 120 is configured to receive a reference voltage. The variable capacitor 120 is further coupled with the logic circuit 130, and configured to adjust the capacitance value according to the control of the logic circuit 130. The current source I2 is coupled in series with the resistor R1, and a second input terminal of the amplifier 110 is coupled between the current source I2 and a first terminal of the resistor R1 through a node N2, wherein a second terminal of the resistor R1 is configured to receive the reference voltage.

The switching circuit 140 is coupled with the amplifier 110, the variable capacitor 120, the logic circuit 130, the voltage source 150, and the noise suppression circuit 160. By a switching operation of the switching circuit 140, the circuit system 100 sequentially operates in a calibration phase and a power supplying phase. For example, the switching circuit 140 is configured to disconnect the second input terminal and the output terminal of the amplifier 110, so that the amplifier 110 is operated as a comparator, where the switching circuit 140 further transfers the output voltage VO to the logic circuit 130, so that a capacitance value of the variable capacitor 120 is calibrated according to the output voltage VO in the calibration phase. In the calibration phase, a voltage of the first input terminal of the variable capacitor 120 gradually approximates to a voltage of the second input terminal. For another example, in a power supplying phase, the switching circuit 140 is configured to electrically connect the second input terminal and the output terminal of the amplifier 110 to form a negative-feedback loop of the amplifier 110, such that the negative-feedback loop of the amplifier 110 is utilized to stabilize the output voltage VO. The switching circuit 140 is further configured to provide the output voltage VO to the noise suppression circuit 160, so as to generate an output current IO for driving the load LD in the power supplying phase.

Specifically, the switching circuit 140 includes switches SW1-SW5. The switches SW1, SW3 and SW4 are controlled by a control signal RCKB, and the switch SW5 is controlled by a control signal RCK, where the control signals RCKB and RCK are inverted signals. In addition, the switch SW2 is controlled by a pulse signal CK. The switch SW1 and the resistor R2 are sequentially coupled in series between the voltage source 150 and the node N1. Specifically, a first terminal of the resistor R2 is coupled with the voltage source 150, and a second terminal of the resistor R2 is coupled with the variable capacitor 120 and the first input terminal of the amplifier 110. The switch SW2 is coupled between a first terminal (i.e., the node N1) of the variable capacitor 120 and a second terminal of the variable capacitor 120. The switch SW3 is coupled between a second terminal (i.e., the node N2) and the output terminal of the amplifier 110. The switch SW4 is coupled between the noise suppression circuit 160 and the output terminal of the amplifier 110. The switch SW5 is coupled between the logic circuit 130 and the output terminal of the amplifier 110.

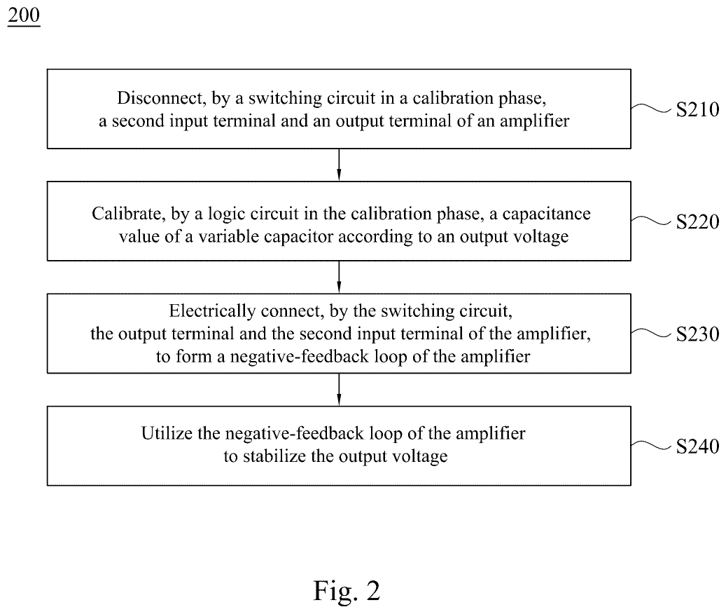

FIG. 2 is a flowchart of an operating method 200 according to an embodiment of the present disclosure. The operating method 200 is applicable to the circuit system 100 in FIG. 1. In some embodiments, any combination of the features of the operating method 200 can be implemented as a plurality of instructions stored in a non-transient computer-readable storage medium. When the instructions are executed by one or more processors, the instructions make part or all of the operating method 200 be executed.

Reference is made to FIG. 1 and FIG. 2. In steps S210-S220, the circuit system 100 operates in a calibration phase. The switches SW1, SW3 and SW4 receiving the control signal RCKB are switched off in the calibration phase, and the switch SW5 receiving the control signal RCK is switched on in the calibration phase. In addition, the switch SW2 is conditionally (e.g., periodically) switched on in the calibration phase. Therefore, in step S210, the switching circuit 140 disconnects the second input terminal and the output terminal of the amplifier 110 in the calibration phase, so that the amplifier 110 is operated as a comparator. In step S220, the logic circuit 130 calibrates a capacitance value of the variable capacitor 120 according to the output voltage VO in the calibration phase, so that a voltage of the first input terminal of the amplifier 110 approximates to a voltage of the second input terminal. The logic circuit 130 is further configured to generate a digit code BC corresponding to the capacitance value of the variable capacitor 120.

After step S220, the circuit system 100 is operated in a power supplying phase and executes steps S230-S240. The switches SW1, SW3 and SW4 receiving the control signal RCKB are switched on in the power supplying phase, and the switch SW5 receiving the control signal RCK is switched off in the power supplying phase. In addition, the switch SW2 maintains switching off in the power supplying phase, that is, the pulse signal CK is switched to a fixed voltage in the power supplying phase, so as to utilize the variable capacitor 120 as a bypass capacitor for filtering. Therefore, in step S230, the switching circuit 140 electrically connects the output terminal and the second input terminal (i.e., the node N2) of the amplifier 110 to form a negative-feedback loop of the amplifier 110. In step S240, the amplifier 110 utilizes the negative-feedback loop to stabilize the output voltage VO.

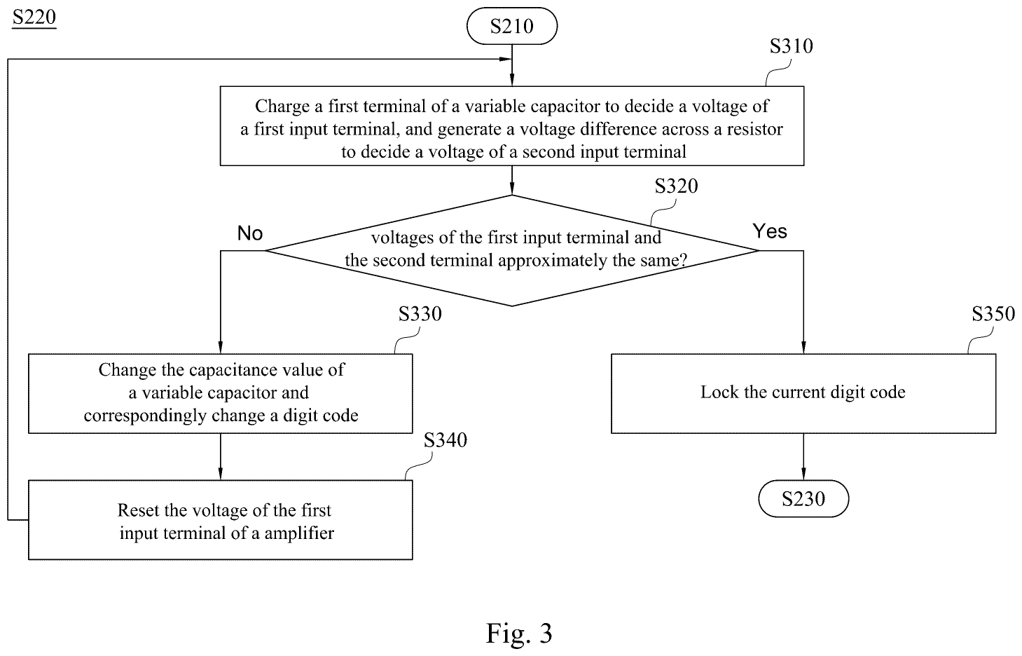

FIG. 3 is a detailed flowchart of step S220 according to an embodiment of the present disclosure, and step S220 includes steps S310-S350. In step S310, the current sources I1 and I2 are enabled. The current source I1 charges the first terminal of the variable capacitor 120 to decide a voltage of the first input terminal (i.e., the node N1) of the amplifier 110. The capacitance value of the variable capacitor 120 corresponds to the digit code BC stored in the logic circuit 130. The current source I2 generates a voltage difference across the resistor R1 to decide a voltage of the second input terminal (i.e., the node N2) of the amplifier 110. In addition, the current sources I1 and I2 are disabled in the following power supplying phase.

In step S320, the switching circuit 140 electrically connects the logic circuit 130 and the output terminal of the amplifier 110, and the logic circuit 130 determines whether the voltage of the first input terminal of the amplifier 110 is approximately the same as the voltage of the second input terminal according to the output voltage VO, where the switching circuit 140 disconnects the logic circuit 130 and the output terminal of the amplifier 110 in the power supplying phase. For example, when the output voltage VO is switched from a high voltage to a low voltage, or from a low voltage to a high voltage, the logic circuit 130 determines whether the voltage of the first input terminal of the amplifier 110 is approximately the same as the voltage of the second input terminal in step S320.

If the judgment in step S320 is “NO”, the logic circuit 130 changes the capacitance value of the variable capacitor 120 and correspondingly changes the digit code BC so that the digit code BC represents the changed capacitance value in step S330. Then, in step S340, the switch SW2 is switched on to reset the voltage of the first input terminal (i.e., the node N1) of the amplifier 110. After step S340, the circuit system 100 repeatedly executes step S310. In some embodiments, when the circuit system 100 repeatedly executes steps S310-S340, the logic circuit 130 can sequentially increases or decreases the capacitance values of the variable capacitor 120. In some embodiments, the switching circuit 140 (e.g., the switch SW2) is configured to periodically reset the voltage of the first input terminal in the calibration phase. For example, the switch SW2 is switched off in steps S310-S320, and is switched on in steps S330-S340.

On the other hand, If the judgment in step S320 is “YES”, the logic circuit 130 executes step S350 to lock the current digit code BC (i.e., no longer change the digit code BC) and ends step S220. In some embodiments, the logic circuit 130 decides capacitance values of other capacitive elements (not shown) in the chip according to the digit code BC obtained in step S220.

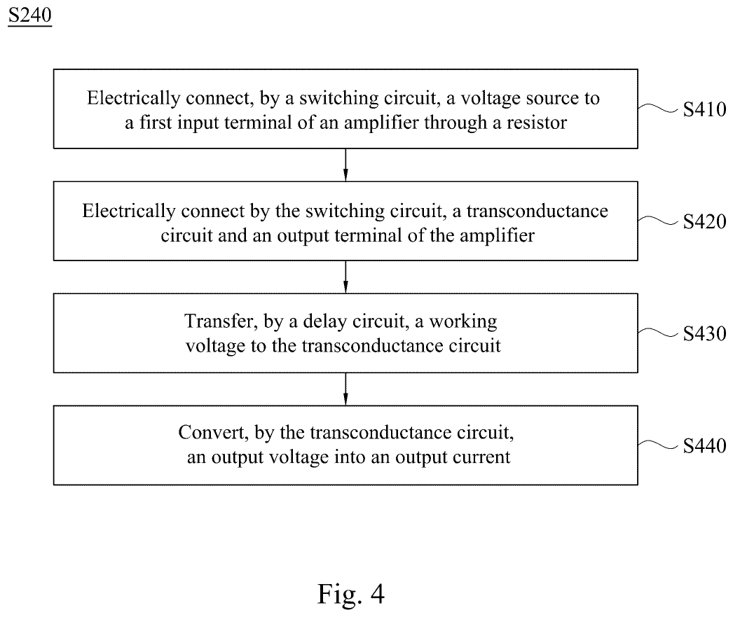

FIG. 4 is a detailed flowchart of step S240 according to an embodiment of the present disclosure, and step S240 includes steps S410-S440. In step S410, the switching circuit 140 electrically connects the voltage source 150 to the first input terminal (i.e., the node N1) of the amplifier 110 through the resistor R2, so that the first input terminal of the amplifier 110 receives an input voltage VI. In the calibration phase, the switching circuit 140 disconnects the voltage source 150 and the first input terminal of the amplifier 110. In some embodiments, the input voltage VI is a bandgap voltage, and in the power supplying phase, the circuit system 100 is operated as a bandgap voltage reference circuit. In some embodiments, the voltage source 150 includes a circuit having a positive voltage temperature coefficient and a circuit having a negative voltage temperature coefficient, and generates a bandgap voltage by mutual compensation of the two circuits. However, the present disclosure is not limited thereto.

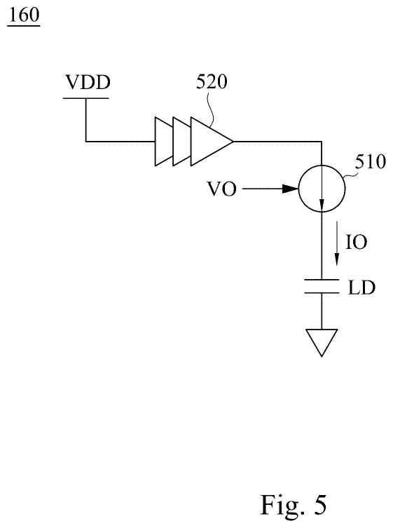

Steps S420-S440 are illustrated in conjunction with FIG. 5. FIG. 5 is a simplified function block diagram of a noise suppression circuit 500 according to an embodiment of the present disclosure. The noise suppression circuit 500 is configured to implement the noise suppression circuit 160 in FIG. 1, and includes a transconductance circuit 510 and a delay circuit 520. The transconductance circuit 510 is coupled with the output terminal of the amplifier 110 through the switching circuit 140 (e.g., the switch SW4), and is coupled with the delay circuit 520 and the load LD. In some embodiments, the delay circuit 520 includes a plurality of inverters coupled in series.

In step S420, the switching circuit 140 electrically connects the transconductance circuit 510 and the output terminal of the amplifier 110, to transfer the output voltage VO to the transconductance circuit 510. In the calibration phase, the switching circuit 140 disconnects the transconductance circuit 510 and the output terminal of the amplifier 110.

In step S430, the delay circuit 520 transfers a working voltage VDD to the transconductance circuit 510, and in some embodiments, the working voltage VDD is the maximum voltage received by the transconductance circuit 510. In some embodiments, due to the voltage coupling effect, the clock signals (not shown) around the circuit system 100 may cause noises in the working voltage VDD, where the delay circuit 520 is configured to reduce the energy of the noises to provide a stable working voltage VDD to the transconductance circuit 510. Then, in step S440, the transconductance circuit 510 converts the output voltage VO into an output current IO.

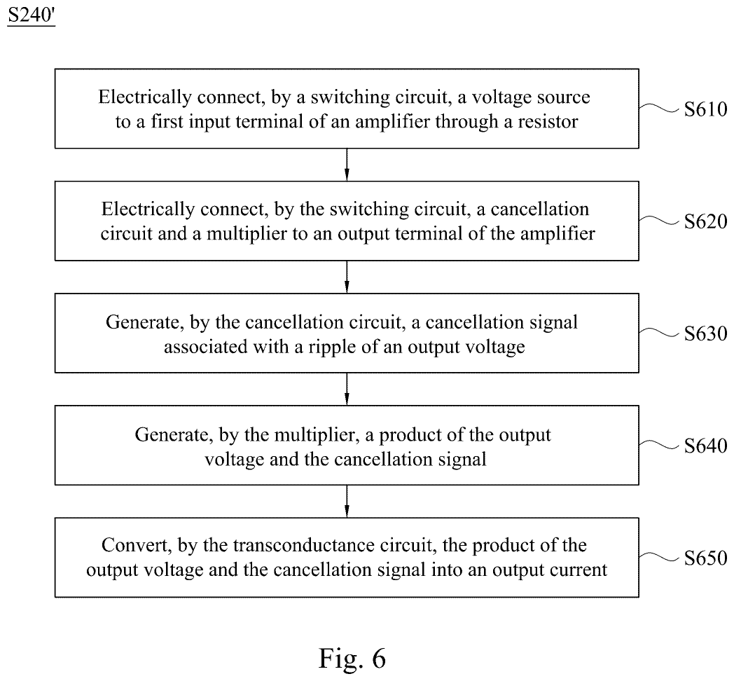

In some embodiments, step S240 in FIG. 2 replaces step S240′ in FIG. 6, where FIG. 6 is a detailed flowchart of step S240′ according to an embodiment of the present disclosure, and step S240′ includes steps S610-S650. Step S610 in FIG. 6 is similar to step S410 in FIG. 4. For the sake of brevity, it is not repeated here.

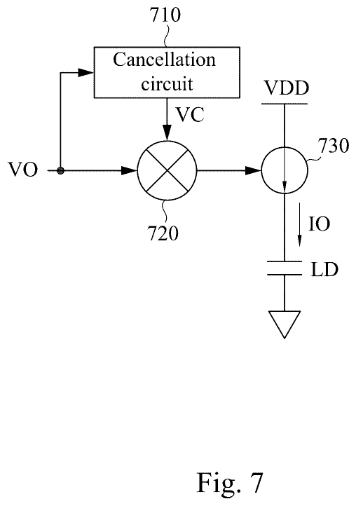

Steps S620-S650 are illustrated in conjunction with FIG. 7. FIG. 7 is a simplified function block diagram of a noise suppression circuit 700 according to an embodiment of the present disclosure. The noise suppression circuit 700 is configured to implement the noise suppression circuit 160 in FIG. 1, and includes a cancellation circuit 710, a multiplier 720, and a transconductance circuit 730. The cancellation circuit 710 is coupled with the output terminal of the amplifier 110 through the switching circuit 140 (e.g., the switch SW4). The multiplier 720 is coupled with the output terminal of the amplifier 110 through the switching circuit 140 (e.g., the switch SW4), and is coupled with the cancellation circuit 710. The transconductance circuit 730 is coupled with the multiplier 720 and the load LD.

In step S620, the switching circuit 140 electrically connects the cancellation circuit 710 and the multiplier 720 to the output terminal of the amplifier 110, to transfer the output voltage VO to the cancellation circuit 710 and the multiplier 720. In the calibration phase, the switching circuit 140 disconnects the cancellation circuit 710 and the output terminal of the amplifier 110, and disconnects the multiplier 720 and the output terminal of the amplifier 110.

In step S630, the cancellation circuit 710 generates a cancellation signal VC associated with a ripple of the output voltage VO. For example, the cancellation circuit 710 can generate a cancellation signal VC including a component inverted with the ripple of the output voltage VO through the Feedforward technology.

Then, in step S640, the multiplier 720 generates a product of the output voltage VO and the cancellation signal VC. In step S650, the transconductance circuit 730 converts the product of the output voltage VO and the cancellation signal VC into the output current IO. In some embodiments, due to the voltage coupling effect, pulse signals (not shown) around the circuit system 100 may cause ripples in the output voltage VO, where the cancellation signal VC of the cancellation circuit 710 is configured to offset the ripples in the output voltage VO, to provide stable output voltage VO to the transconductance circuit 510.

In some embodiments, in steps S230-S240 of the power supplying phase, the circuit system 100 switches the variable capacitor 120 to the maximum capacitance value, thereby improving the filtering effect of a low-pass filter formed by the variable capacitor 120 and the resistor R2.

In some embodiments, when the circuit system 100 is enabled (for example, when connected to a power supply), the circuit system 100 executes steps S210-S220 of the calibration phase, and then execute steps S230-S240 of the power supplying phase, and the circuit system 100 does not repeat the calibration phase, that is, steps S210-S220 are executed only once.

In conclusion, the circuit system 100 can reuse the amplifier 110 and the variable capacitor 120 in the execution of the calibration phase and the power supplying phase. Therefore, the circuit system 100 saves the layout area of at least one amplifier and a variable capacitor, which facilitates saving costs and improving the space utilization efficiency of the chip.

The expressions “about”, “approximately” or “roughly” used herein generally means that the error or range of an index value is usually within 20%, preferably within 10%, and more preferably within 5%. Unless expressly stated, the values mentioned are regarded as approximate values, i.e., the error or range represented by, such as “about”, “approximately” or “roughly”.

Some terms are used in the description and claims to refer to specific elements. However, those skilled in the art should understand that the same element may be referred to by different terms. The description and the claims are not based on the difference in name as a way to distinguish elements, but rather on the difference in function of the elements. The “including” mentioned in the description and the claims is an open term, so it should be interpreted as “including, but not limited to”. In addition, “coupling” includes any direct and indirect means of connection. Therefore, if it is described that the first element is coupled with the second element, it means that the first element can be directly connected to the second element through electrical connection or wireless transmission, optical transmission and other signal connection methods, or indirectly connected to the second element by other elements or connection means.

In addition, unless otherwise specified in the description, any singular term includes plural meanings.

The above are only preferred embodiments of the present disclosure, and any modification and equivalent change can be performed on the present disclosure, without departing from the scope or spirit of the present disclosure. In summary, all modifications and equivalent changes made to the present disclosure within the scope of the following claims fall within the scope of the present disclosure.

What is claimed is:

1. A circuit system, comprising:
an amplifier, comprising a first input terminal, a second input terminal and an output terminal, wherein the output terminal is configured to generate an output voltage;
a variable capacitor coupled with the first input terminal; and
a switching circuit coupled with the amplifier and the variable capacitor,
wherein in a calibration phase, the switching circuit is configured to disconnect the second input terminal and the output terminal, so that the amplifier is operated as a comparator, and wherein a capacitance value of the variable capacitor is calibrated according to the output voltage, so that a voltage of the first input terminal approximates to a voltage of the second input terminal; and
wherein in a power supplying phase, the switching circuit is configured to electrically connect the second input terminal and the output terminal to form a negative-feedback loop of the amplifier, such that the negative-feedback loop of the amplifier is utilized to stabilize the output voltage.

2. The circuit system according to claim 1, further comprising:
a first current source coupled with the first input terminal, and the first current source being configured to be enabled in the calibration phase to charge the variable capacitor and configured to be disabled in the power supplying phase;
a first resistor; and
a second current source coupled in series with the first resistor, wherein the second input terminal is coupled between the first resistor and the second current source, and wherein the second current source is configured to be enabled in the calibration phase and configured to be disabled in the power supplying phase.

3. The circuit system according to claim 2, wherein the switching circuit is configured to periodically reset the voltage of the first input terminal in the calibration phase.

4. The circuit system according to claim 1, further comprising:
a logic circuit coupled with the output terminal through the switching circuit, and the logic circuit being configured to calibrate the capacitance value of the variable capacitor according to the output voltage and generate a digit code corresponding to the capacitance value of the variable capacitor,
wherein the switching circuit is configured to electrically connect the logic circuit and the output terminal in the calibration phase and disconnect the logic circuit and the output terminal in the power supplying phase.

5. The circuit system according to claim 1, further comprising:
a voltage source coupled with the variable capacitor and the first input terminal through the switching circuit, and the voltage source being configured to provide an input voltage,
wherein the switching circuit is configured to disconnect the voltage source and the first input terminal in the calibration phase and electrically connect the voltage source and the first input terminal in the power supplying phase, so that the first input terminal receives the input voltage.

6. The circuit system according to claim 5, further comprising:
a second resistor, wherein a first terminal of the second resistor is coupled with the voltage source, and a second terminal of the second resistor is coupled with the variable capacitor and the first input terminal.

7. The circuit system according to claim 5, wherein the input voltage is a bandgap voltage.

8. The circuit system according to claim 1, further comprising:
a transconductance circuit coupled with the output terminal through the switching circuit and configured to convert the output voltage into an output current; and
a delay circuit coupled with the transconductance circuit and configured to provide a working voltage to the transconductance circuit,
wherein the switching circuit is configured to disconnect the transconductance circuit and the output terminal in the calibration phase and electrically connect the transconductance circuit and the output terminal in the power supplying phase.

9. The circuit system according to claim 1, further comprising:
a cancellation circuit coupled with the output terminal through the switching circuit and configured to generate a cancellation signal associated with a ripple of the output terminal;
a multiplier coupled with the output terminal through the switching circuit and coupled with the cancellation circuit, and configured to generate a product of the output voltage and the cancellation signal; and
a transconductance circuit coupled with the multiplier and configured to convert the product of the output voltage and the cancellation signal into an output current,
wherein the switching circuit is configured to disconnect the cancellation circuit and the output terminal and disconnect the multiplier and the output terminal in the calibration phase, and configured to electrically connect the output terminal to the cancellation circuit and the multiplier in the power supplying phase.

10. The circuit system according to claim 1, wherein when the circuit system is enabled, the circuit system executes the calibration phase and then executes the power supplying phase, and the circuit system does not repeat the calibration phase.

11. The circuit system according to claim 1, wherein in the power supplying phase, the variable capacitor is switched to a maximum capacitance value.

12. An operating method applicable to a circuit system, wherein the circuit system comprises an amplifier, a variable capacitor and a switching circuit; the switching circuit is coupled with the amplifier and the variable capacitor; the amplifier comprises a first input terminal, a second input terminal and an output terminal; and the output terminal is configured to generate an output voltage, wherein the operating method comprises:
in a calibration phase, utilizing the switching circuit to disconnect the second input terminal and the output terminal, so that the amplifier is operated as a comparator;
in the calibration phase, calibrating a capacitance value of the variable capacitor according to the output voltage, so that a voltage of the first input terminal approximates to a voltage of the second input terminal;
in a power supplying phase, utilizing the switching circuit to electrically connect the second input terminal and the output terminal to form a negative-feedback loop of the amplifier; and
in the power supplying phase, utilizing the negative-feedback loop of the amplifier to stabilize the output voltage.

13. The operating method according to claim 12, wherein calibrating the capacitance value of the variable capacitor according to the output voltage comprises:
enabling a first current source of the circuit system to charge the variable capacitor, wherein the first current source is configured to be disabled in the power supplying phase; and
enabling a second current source of the circuit system, wherein the second current source is coupled in series with a first resistor, the second input terminal is coupled between the first resistor and the second current source, and the second current source is configured to be disabled in the power supplying phase.

14. The operating method according to claim 13, wherein calibrating the capacitance value of the variable capacitor according to the output voltage comprises:
utilizing the switching circuit to periodically reset the voltage of the first input terminal.

15. The operating method according to claim 12, wherein the circuit system further comprises a logic circuit that is coupled with the output terminal through the switching circuit, wherein calibrating the capacitance value of the variable capacitor according to the output voltage comprises:
utilizing the switching circuit to electrically connect the logic circuit and the output terminal, wherein the switching circuit is configured to disconnect the logic circuit and the output terminal in the power supplying phase;
utilizing the logic circuit to calibrate the capacitance value of the variable capacitor according to the output voltage; and
utilizing the logic circuit to generate a digit code corresponding to the capacitance value of the variable capacitor.

16. The operating method according to claim 12, wherein the circuit system further comprises a voltage source that is coupled with the variable capacitor and the first input terminal through the switching circuit, wherein utilizing the negative-feedback loop of the amplifier to stabilize the output voltage comprises:
utilizing the switching circuit to electrically connect the voltage source to the first input terminal through a second resistor of the circuit system, so that the first input terminal receives an input voltage from the voltage source, wherein the switching circuit disconnects the voltage source and the first input terminal in the calibration phase.

17. The operating method according to claim 16, wherein the input voltage is a bandgap voltage.

18. The operating method according to claim 12, wherein the circuit system further comprises a transconductance circuit and a delay circuit coupled to each other, and wherein utilizing the negative-feedback loop of the amplifier to stabilize the output voltage comprises:
utilizing the switching circuit to electrically connect the transconductance circuit and the output terminal, wherein the switching circuit disconnects the transconductance circuit and the output terminal in the calibration phase;
utilizing the delay circuit to provide a working voltage to the transconductance circuit; and
utilizing the transconductance circuit to convert the output voltage into an output current.

19. The operating method according to claim 12, wherein the circuit system further comprises a cancellation circuit, a multiplier and a transconductance circuit;
the cancellation circuit and the multiplier are coupled with the output terminal through the switching circuit, the multiplier is coupled with the cancellation circuit, and the transconductance circuit is coupled with the multiplier, wherein utilizing the negative-feedback loop of the amplifier to stabilize the output voltage comprises:
utilizing the switching circuit to electrically connect the output terminal to the cancellation circuit and the multiplier, wherein the switching circuit is configured to disconnect the cancellation circuit and the output terminal and disconnect the multiplier and the output terminal in the calibration phase;
utilizing the cancellation circuit to generate a cancellation signal associated with a ripple of the output voltage;
utilizing the multiplier to generate a product of the output voltage and the cancellation signal; and
utilizing the transconductance circuit to convert the product of the output voltage and the cancellation signal into an output current.

20. The operating method according to claim 12, further comprising:
in the power supplying phase, switching the variable capacitor to a maximum capacitance value.
